(19) United States
(12) Patent Application Publication
(10) Pub. No.: US 2026/0221753 A1
(43) Pub. Date: Jul. 30, 2026

(54) SWITCHING DEVICE

(71) Applicant: Ellenberger & Poensgen GmbH, Altdorf (DE)

(72) Inventors: Hendrik-Christian KOEPF, Nuernberg (DE); Alexander LABS, Winkelhaid (DE); Peter STEEGMUELLER, Nuernberg (DE)

(73) Assignee: Ellenberger & Poensgen GmbH, Altdorf (DE)

(21) Appl. No.: 19/461,017

(22) Filed: Jan. 27, 2026

(30) Foreign Application Priority Data
Jan. 27, 2025 (DE) 10 2025 102 794.3

(51) Int. Cl. H02H 3/087; H02H 1/00; H02H 1/04; H02H 3/02; H02H 3/10

(52) U.S. Cl. CPC H02H 3/087; H02H 1/0007; H02H 1/04; H02H 3/025; H02H 3/10

(57) ABSTRACT

A switching device having two terminals that are electrically connected via a first current path that has a mechanical switch. The switching device also includes a second current path that is electrically wired in parallel with the first current path and that has a bridge rectifier with an AC voltage side and a DC voltage side. The AC voltage side is connected to the terminals, and the DC voltage side is electrically connected via a switch unit. The invention also relates to a circuit breaker.

This nonprovisional application claims priority under 35 U.S.C. § 119(a) to German Patent Application No. 10 2025 102 794.3, which was filed in Germany on January 27, 2025, and which is herein incorporated by reference.

### BACKGROUND OF THE INVENTION

### Field of the Invention

The invention relates to a switching device. The switching device includes two terminals that are electrically connected via a first current path that has a mechanical switch. The invention also relates to a circuit breaker having such a switching device.

### Description of the Background Art

Customarily, circuit breakers are used to protect an electrical line or a device from a malfunction of the associated circuit, for example an excessive applied voltage or an excessive flowing electric current. This occurs, for example, when there is previous damage to the device to be protected or to the electrical line. In this case, an interruption of the current flow is accomplished via the circuit breaker so that further damage is avoided.

For the purpose of interrupting the current flow, the circuit breaker has a switching device with a switch. The switch in this case is arranged inside a housing in order to provide shock-hazard protection and for easy installation. The switch is designed as a semiconductor switch, for example. On account of its design, it has an internal resistance, for which reason it heats during operation, at least when a relatively high electric current is carried. Consequently, cooling is necessary. Efficiency is also reduced. In an alternative thereto, the switch is mechanical in design and is operatively connected to a drive, which includes an electromagnet, for example. It is therefore possible to change the switching state of the switch by supplying power to the drive. If the voltage to be switched here is relatively high, it is possible for an arc to form when the mechanical switch is opened.

Known from WO 2010/108565 A1, which corresponds to US 2012/0007657, which is incorporated herein by reference, is a hybrid switch (hybrid disconnect switch) with a mechanical switch or disconnecting element and, wired in parallel therewith, semiconductor electronics that include a semiconductor switch, preferably an IGBT. The semiconductor electronics have no additional energy source and, when the mechanical switch is closed, are current-blocking, i.e., virtually without current and voltage. To interrupt the current via the hybrid switch, the mechanical switch is opened, in which case the arc can arise. The energy of the arc arising upon opening of the mechanical switch is used by the semiconductor electronics, wherein the semiconductor electronics are wired to the mechanical switch in such a manner that the arc voltage across the mechanical switch (as a result of the arc) when it is opening switches the semiconductor switch into a conductive state.

In a design of this nature, the full voltage applied to the hybrid switch and the electric current carried thereby, each of which can be relatively high, are therefore switched by the semiconductor switch, namely by the IGBT. Consequently, demands on the IGBT are increased, for which reason it is relatively costly. In this design, it is only possible to switch a flow of electric current in one current direction via the IGBT, for which reason attention must be paid to the correct orientation during installation of the hybrid switch. If the orientation is incorrect, it would not be possible to switch the electric current, and therefore no safety function would be realized via the circuit breaker.

### SUMMARY OF THE INVENTION

It is therefore an object of the present invention is to provide an especially suitable switching device and an especially suitable circuit breaker, wherein manufacturing costs are advantageously reduced and wherein installation is usefully simplified and/or a susceptibility to errors in this regard is reduced.

The switching device serves, for example, to switch an electric current, which is to say in particular to establish and/or interrupt a flow of electric current. For this purpose, the switching device expediently has two states, namely an electrically conductive state, which is also referred to as a closed state. In this case it is possible to carry the electric current via the switching device. In the other state, which is referred to as an open or electrically nonconductive state, a flow of electric current through the switching device is not possible, in particular. For example, the switching device is/can be manually actuated, so that the switching device is a manual switch. Alternatively or in combination herewith, it is possible, for example, to actuate the switching device electrically, and hence remotely, in particular. In another alternative, the switching device is, for example, actuated automatically, expediently as a function of certain conditions. Suitably, the switching device is a component part of a circuit breaker or of a contactor.

The circuit breaker serves, for example, to protect a device, and the circuit breaker is, e.g., an equipment circuit breaker. Alternatively or in combination therewith, the circuit breaker serves to protect a line and is thus a line circuit breaker. In particular, the circuit breaker is used in a DC circuit, which is to say, e.g., between a load and a DC link or the like, so that, in particular, a circuit is formed. Preferably, a DC voltage between 400 V and 650 V is present in the DC circuit in this case, which is to say relatively high DC voltage, in particular. Preferably, the circuit breaker is used to protect an actuator in an industrial plant. Here, the actuator constitutes the load, in particular. Expediently, the circuit breaker is used in the area of industrial automation. In particular, the voltage switched via the circuit breaker is 24 V, 48 V, 380 V, 650 V, 760 V. In an alternative, the circuit breaker is used to protect street lighting, a ship electrical system, railway infrastructure applications, railway drive applications, or in the area of electrified aviation. In another alternative, the circuit breaker is used in the expansion and integration of renewable energy producers, in off-grid power systems, in the private domestic field, in greenhouses, in the electrification of road-bound mobility (electromobility), agriculture, or in construction vehicles. The (DC) voltage used here is between 1500 V and 3000 V or measures 110 V, 380 V, 400 V 800 V, 1000 V, 1500 V, 3000 V, for example. In summary, as an alternative to use in an industrial plant, the circuit breaker is used, for example, in an electric vehicle, such as a motor vehicle, an aircraft, or a ship/boat.

The switching device can also be designed, e.g., as a disconnect switch, or is a component part thereof, also referred to as a disconnector. For example, the switching device includes a mechanical lever via which the switching state of the control device can be changed.

The switching device includes two terminals, to which additional component parts of the circuit are connected in the installed state. The terminals are suitable, in particular provided and equipped, for this purpose. Expediently, a cable or a bus bar is connected to the respective terminal for this purpose, wherein a cross section thereof is, e.g., between 10 mm² and 100 mm², or between 25 mm² and 92 mm². The cross section measures, for example, 16 mm², 25 mm², or 35 mm². The cross section is, for example, 6 mm², between 6 mm² and 16 mm², or between 16 mm² and 50 mm². In particular, the terminals are designed in the manner of cage clamps or at least include them.

The two terminals can be electrically connected to one another via a first current path. For example, in this case the two terminals make direct electrical contact with one another via the first current path, or yet another component is electrically wired in series with the first current path, through which component and the first current path the two terminals are then electrically connected to one another. The first current path is suitably arranged in a housing that preferably is made of a plastic. Consequently, shock-hazard protection is provided, and this path is protected from environmental influences as well. Expediently, the possible terminals can be incorporated into the housing, so that it is possible to make electrical contact with the first current path from outside the housing. Expediently, the housing constitutes an outer boundary of the switching device, and all further component parts are arranged inside the housing, and therefore protected.

The first current path, and thus the switching device, can have a mechanical switch. Consequently, the mechanical switch is electrically wired between the two terminals of the switching device. Therefore, it is possible to switch a flow of electric current through the first current path via the mechanical switch. For example, the first current path has yet more components, or, e.g., the first current path is formed only via the mechanical switch and any electric lines, such as bus bars, that lead to the electrical, mechanical switch. As a result, manufacturing costs are reduced.

The switching device also can have a second current path that is electrically wired in parallel with the first current path. Consequently, the two terminals are also electrically connected to one another via the second current path. If the first current path makes direct electrical contact with the two terminals, then the second current path therefore also makes direct electrical contact with the terminals. If, in contrast, the first current path makes electrical contact with one of the terminals through an additional component, then the second current path is also electrically wired in series with this component.

The second current path can have a bridge rectifier that has an AC voltage side and a DC voltage side. In this case, the bridge rectifier includes two bridge arms that are electrically wired in parallel between the AC voltage side terminals that form the AC voltage side. Each bridge arm has, at its midpoint, one of the DC voltage side terminals, via which the DC voltage side of the bridge rectifier is formed. The bridge rectifier expediently is configured to be passive, and consequently is designed as a diode rectifier. Expediently, each of the two bridge arms has two diodes electrically wired in series in each case, wherein their reverse directions are antiparallel to one another, and wherein the two bridge arms are different from one another. A bridge rectifier of this nature is also referred to as a two-pulse bridge rectifier circuit B2.

The DC voltage side is electrically connected via a switch unit, so that it is, or at least can be, short-circuited via the switch unit, for example. The switch unit is therefore electrically connected to the DC voltage side terminals. In this case it is possible to place the switch unit in an electrically conductive state and in an electrically nonconductive state. If the switch unit is in the electrically conductive state, which to say is closed, then the two DC voltage side terminals make low-resistance electrical contact with one another. If, in contrast, the switch unit is open, or in other words is in the electrically nonconductive state, then the two DC voltage side terminals are connected to one another with high resistance or are galvanically isolated from one another. Consequently, no significant flow of electric current through the bridge rectifier is allowed, and therefore also none through the second current path. For example, an additional component is wired between the switch unit and at least one of the DC voltage side terminals. Especially preferably, however, the switch unit makes direct electrical contact with DC voltage side terminals. As a result, manufacturing costs are reduced.

With the switch unit, it is thus possible, in order to interrupt the electric current, to first place the switch unit in the electrically conductive state, if this is not yet the case, and then to open the mechanical switch. As a result, the electric current commutates fully to the second current path, for which reason no arc forms in the mechanical switch during the opening process, or the arc collapses. Thus, no erosion occurs there, and no thermal stress is present. When the switch unit is subsequently opened, which is to say is brought into the electrically nonconductive state, there is likewise no formation of an arc. In a different mode of operation, the mechanical switch is opened first, and then, when an arc forms, the switch unit is placed in the electrically conductive state for a certain period of time so that the electric current commutates from the first current path to the second current path and the arc collapses. Subsequently, the switch unit is likewise placed in the electrically nonconductive state. It is thus also the case here that the time period during which the electric current is still carried is limited in time, and a period during which the electric current is carried via the switch unit is shortened.

On account of the bridge rectifier, it is possible to switch the flow of electric current in both current directions, even when the switch unit is suitable, as well as provided and equipped, only for switching the flow of electric current in a single current direction. Consequently, manufacturing costs are reduced. It is thus possible, in particular, for the switch unit to use a semiconductor switch, such as a field-effect transistor, a MOSFET, or an IGBT. In particular, the switch unit includes such a semiconductor switch or is formed therewith. In summary, it is not necessary to design the semiconductor switch to be bidirectional, for which reason manufacturing costs are reduced. Nor is it necessary to pay attention to polarity when connecting additional component parts of the possible circuit to the terminals, for which reason installation is simplified. Incorrect installation is precluded here, which improves safety. Moreover, it is also possible to switch a possible reverse current via the switching device, for example if the reverse current arises on account of a fault or the like, despite its use in the DC circuit. In this case, the reverse current is oriented in the opposition direction of current from the direction of current in which the electric current is carried in normal operation.

For example, the mechanical switch is only manually actuatable. Especially preferably, however, a drive is present, by which means the mechanical switch is driven. It is thus possible to change the switching state of the mechanical switch by operating the drive. For example, in this case it is only possible to change the switching state of the mechanical switch in one direction, which is to say, for example, only from the electrically conductive state to the electrically nonconductive state or vice versa. Consequently, the design is simplified. Especially preferably, however, it is possible to change the switching state of the mechanical switch in both directions via the drive, or in other words to place it in the electrically conductive state as well as the electrically nonconductive state. A functionality is improved as a result. For example, the drive is mechanical in design. Especially preferably, however, the drive is electrical in design. For example, the combination of the mechanical switch and the drive forms a relay. Expediently, the drive includes an electric coil. In this case, a magnetic component, for example a permanent magnet or a ferromagnetic component, suitably is moved within the coil during operation of the drive.

The drive is designed as a moving magnet actuator, for example. The magnetic component, which is movably mounted, is also associated with the moving magnet actuator in this case. In addition, the moving magnet actuator has a drive unit with one or more electric coils, which are supplied with current upon actuation of the drive, so that a magnetic interaction between them and the component takes place. The electric coils are held in a fixed position in this case. Since the electric coil(s) is/are held stationary, design is simplified, and, with the exception of the components necessary for the mounting, no additional movable components or electrical connections between the movable components, namely the component, and the stationary components of the moving magnet actuator, are necessary. Friction of the moving magnet actuator, which is also referred to below simply as actuator, is also reduced as a result.

The drive unit can include two electric coils, which are identical in design, for example. At a minimum, however, the two electric coils are arranged offset from one another along a longitudinal axis and concentric to said axis. The component in this design is located on the longitudinal axis, in particular, and is movably mounted along the same. In one switching state of the mechanical switch, in this case, the component is located in an air gap that is present between the two electric coils and is held there via a magnetic short-circuit plate, for example. In the other switching state, in contrast, the component is offset along the longitudinal axis.

Since the number of movable component parts of the moving magnet actuator is relatively small, in particular only the component, and these have a relatively low weight, in particular, a dynamic response of the actuator is relatively high. As a result, an inertia during actuation of the mechanical switch is reduced. Consequently, relatively fast switching is made possible by the switching device.

For example, the switching device can be formed with the individual component parts. Especially preferably, however, the switching device includes an additional mechanical switch that is electrically wired between the terminals in series with the first current path and with the second current path. Galvanic isolation can therefore be achieved by this means in the event that the switch unit is not designed to be galvanically isolating.

For example, the mechanical switch can include only a single moving contact. Especially preferably, however, the mechanical switch has a contact cross-bar with two moving contacts. The contact cross-bar is movably mounted. It is possible in this case to bring each of the moving contacts into direct mechanical contact with one associated fixed contact each or to space them apart from one another. Consequently, the mechanical switch is suitably designed in the manner of a double contact breaker, for which reason the voltage applied between each fixed contact and the associated moving contact is reduced in the open switching state of the mechanical switch. As a result, formation of an arc is suppressed there, or it does not occur until a relatively high applied voltage. The contact cross-bar is mounted to be transversally movable, in particular.

Expediently, an extinguishing chamber is associated with each fixed contact and the associated moving contact. If only one fixed contact and one moving contact are present, the extinguishing chamber preferably is likewise associated with them. An extinguishing of the relevant arc, in particular, is accomplished in this case via the extinguishing chamber. For this purpose, the extinguishing chamber expediently includes multiple quenching plates or the like.

For example, the switch unit can include only a single semiconductor switch. This is designed, for example, as a field-effect transistor, such as a MOSFET, or as an IGBT or GTO. Especially preferably, however, the switch unit has multiple semiconductor switches electrically wired in series. In this case, the direction of current that can be switched via each of the semiconductor switches, in particular, is the same and is chosen as a function of the bridge rectifier. As a result, it is possible, in particular, to interrupt the electric current only in one direction via the switch unit, even though multiple semiconductor switches are present. For example, the switch unit includes exactly two or three appropriate semiconductor switches. Suitably, the number of semiconductor switches is less than 10, for which reason a cost is reduced. In particular, a type of cascode is therefore formed via the semiconductor switches, and/or they are wired together in the manner of a cascode.

Each of the semiconductor switches can be electrically bridged via a resistive element. A specific electrical resistance, which is, e.g., constant or variable, is provided by the resistive elements in each case here. In particular, the respective electrical resistance in this case is a function of a specific state of the switching device and/or external specifications. In particular, the electrical resistance is a function of an electric current carried by the switching device and/or a voltage applied thereto.

The resistive elements provide, for example, a voltage divider, via which the voltage across each of the semiconductor switches is reduced. Consequently, the demands on the semiconductor switches are reduced, and it is possible to use relatively inexpensive components, or at least semiconductor switches for which the maximum switchable voltage is reduced. Thus, even though more semiconductor switches are present, they are disproportionately less expensive, for which reason production costs as a whole are reduced. In this case, it is only necessary to actuate the semiconductor switches essentially simultaneously, so that the voltage applied to the terminals is applied to one of the semiconductor switches, at least not for a relatively long period of time.

In particular, the switch unit is modular in design here and has, for example, multiple appropriate sockets into which the respective semiconductor switch and the corresponding resistive elements are then inserted. Preferably, a submodule is formed in this case via each of the resistive elements and the associated semiconductor switch. Expediently, multiple appropriate sockets are present, in some of which is inserted one of the submodules, in particular as a function of the voltage to be switched. The other sockets preferably are connected to one another via a shorting jumper. As a result, it is possible to match the number of submodules used to the voltage to be switched, wherein identical parts can be used so that manufacturing costs are further reduced. When relatively high voltages are to be switched, shorting jumpers are replaced by submodules, in particular.

For example, the resistive elements can be different from one another. It is therefore possible to match them to different resistive element values. Especially preferably, however, the resistive elements are identical in design to one another. As a result, the voltage arising at the semiconductor switch bridged via the respective resistive element is the same when it is electrically nonconductive, thus simplifying design and operation. Also, it is possible to use identical parts on account of the identical design, thus reducing manufacturing costs. In particular, the semiconductor switches are also identical in design to one another in this case.

For example, the resistive elements are ohmic resistors. As a result, manufacturing costs are reduced. Alternatively or in combination therewith, the resistive elements, or at least some of them, are designed as temperature-dependent resistors, which increases safety. Especially preferably, however, the resistive elements are varistors. By this means, the maximum voltage across the semiconductor switches is limited in this case, and it is matched to the respective semiconductor switches used, in particular. If a malfunction should be present upon opening or upon closing of one of the semiconductor switches, or if this does not occur synchronously on account of manufacturing tolerances or prevailing conditions, but instead with a time offset, it is possible that some of the semiconductor switches are open while others are closed. As a result, a higher voltage arises at the semiconductor switches that are open, which is to say nonconductive. Damage to them is prevented via the varistors, and when all semiconductor switches are in the electrically nonconductive state or in the electrically conductive state, electric current is no longer carried by the varistors, so that the original functionality of the semiconductor switches is then available once more. In summary, the demands on the control of the semiconductor switches are reduced on account of the varistors, thus reducing manufacturing costs.

Preferably, an ohmic resistor is designed such that it is electrically wired in parallel with one of the semiconductor switches. For example, this ohmic resistor is provided via one of the resistive elements, or the ohmic resistor is electrically wired in parallel with one of the resistive elements in addition. On account of the ohmic resistor, it is therefore possible to place the semiconductor switches in the electrically conductive state, with the exception of the semiconductor switch bridged by the ohmic resistor, so that an electric current is carried via the second current path. On account of the ohmic resistor, this current is limited, however, so that the switching device can also be used for precharging in the possible circuit/DC circuit. In this case, the mechanical switch is in the electrically nonconductive state.

For example, only the ohmic resistor is present, or it is electrically wired in series with an electric coil, and thus the associated semiconductor switch is bridged via the series connection. Especially preferably, one of the semiconductor switches is bridged via the ohmic resistor as well as via the series connection from (a different) ohmic resistor and the coil. Alternatively or in combination therewith, this semiconductor switch is bridged via a temperature-dependent resistor. On account of this approach, it is possible to relatively exactly set the electric current carried via the second current path for precharging when the mechanical switch is open. As a result, the use of the switching device for precharging is improved.

Alternatively, or especially preferably in combination therewith, a capacitor is electrically wired in parallel with another of the semiconductor switches. For example, the resistive element is formed via the capacitor, or especially preferably, the capacitor is wired in parallel with the resistive element associated with the same semiconductor switch. The capacitor acts in the manner of a voltage divider, and the voltage arising across the associated semiconductor switch is limited. Moreover, voltage and/or current spikes that arise are limited via the capacitor, for which reason losses occurring upon actuation of the semiconductor switch are also reduced.

For precharging, in this design the semiconductor switch with which the ohmic resistor is electrically wired in parallel, in particular, is placed in the electrically conductive state. The semiconductor switch with which the capacitor is electrically wired in parallel is placed in the electrically conductive state, at least temporarily, so that the electric current is carried via the switching device. When this current is relatively high and/or after a specific period of time, the semiconductor switch with which the capacitor is electrically wired in parallel is placed in the electrically nonconductive state. On account of the capacitor, the voltage that arises is limited, as are voltage spikes that arise, preventing destruction.

The circuit breaker serves, in particular, to interrupt an electric current when a fault condition is present, for example an overcurrent and/or a short-circuit current. Alternatively or in combination therewith, the flow of electric current is interrupted via the circuit breaker when an applied voltage is excessive or it has been detected that an arc is present. The circuit breaker has a sensor for this purpose, by which means the possible fault condition can be detected, in particular. The sensor here serves, in particular, to detect a state of the circuit breaker and/or of the electric current carried via the circuit breaker.

Furthermore, the circuit breaker has a switching device with two terminals that are electrically connected via a first current path that has a mechanical switch. The switching device additionally includes a second current path that is electrically wired in parallel with the first current path and that has a bridge rectifier with an AC voltage side and a DC voltage side. The AC voltage side is connected to the terminals, and the DC voltage side is electrically connected via a switch unit. Expediently, the terminals of the switching device constitute the terminals of the circuit breaker, and/or the switching device has a housing that also constitutes the housing of the circuit breaker.

In particular, the sensor is electrically wired in series with the first and/or second current path. Alternatively thereto, the sensor is electrically wired in parallel with the first and the second current path. Expediently, multiple appropriate sensors are present, so that a relatively exact determination of different fault sources is made possible. In this case, one of the sensors is designed as a voltage sensor and another as a current sensor, for example.

The circuit breaker further includes a control unit that is connected to the sensor by a signal. The switching device, namely the mechanical switch and the switch unit, is actuated via the control unit. They are placed in the electrically nonconductive state, in particular, when the fault condition has been detected via the sensor. In particular, the application of a suitable voltage to the switch unit and/or a supply of power to the possible drive is accomplished via the control unit in this case. When the fault condition is present, the mechanical switch is opened, in particular via the control unit, and thus is placed in the nonconductive state. Afterwards or shortly beforehand, the switch unit is placed in the conductive state so that the electric current between the two terminals commutates to the second current path. When this occurs and the mechanical switch is open far enough, then the switch unit is also placed in the electrically nonconductive state so that the flow of electric current between the two terminals is completely suppressed. For example, the possible additional mechanical switch is additionally present here. This switch expediently is opened when the flow of electric current between the terminals is completely suppressed so that no electric arc occurs there as well. However, the two terminals are then galvanically isolated from one another.

The improvements and advantages explained in connection with the switching device should also be applied correspondingly to the circuit breaker, and to one another, and vice versa.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 schematically shows a DC circuit with a load and a circuit breaker, and

FIG. 2 shows a simplified circuit diagram of the circuit breaker that includes a switching device.

### DETAILED DESCRIPTION

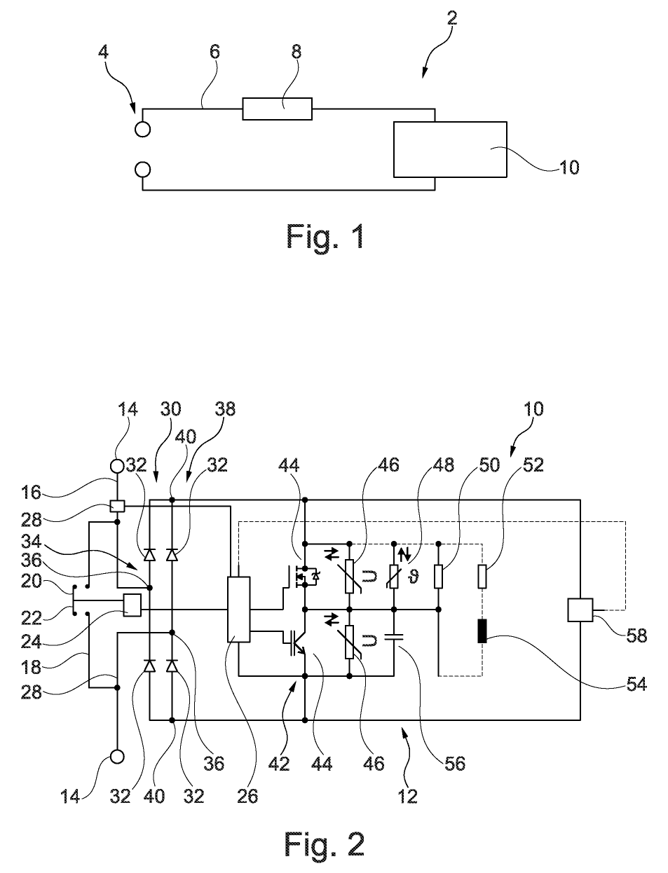

Shown in a schematically simplified manner in FIG. 1 is a DC circuit 2, which includes a DC voltage source 4. This provides a DC voltage of 650 V, which feeds a DC link 6. This powers a load 8 that is electrically connected to the DC link 6 through a circuit breaker 10.

Shown in FIG. 2 is a circuit diagram of the circuit breaker 10. The circuit breaker 10 has a switching device 12, which includes two terminals 14. The terminals 14 in this case also constitute the terminals of the circuit breaker 10, and, in the installed state, a line of the DC link 6 is connected to one, and a line leading to the load 8 is connected to the other. The two terminals 14 are electrically connected to one another via an additional current path 16 and a first current path 18 of the switching device 12, which are electrically wired in series.

The first current path 18 has a mechanical switch 20, which is designed as a double contact breaker. For this purpose, the mechanical switch 20 has a contact cross-bar 22 that is mounted so as to be movable at right angles to its direction of extent, and with each of whose ends is associated a moving contact. Moving the contact cross-bar 22 makes it possible to place each moving contact against one associated fixed contact or to space it apart therefrom. When the moving contacts rest against the fixed contacts, the mechanical switch 20 is closed, and hence electrically conductive. When they are spaced apart, in contrast, the mechanical switch 20 is open, and a flow of electric current through them is not possible.

The mechanical switch 20 is driven via a drive 24 of the switching device 12 so that a type of relay is formed. The drive 24 in this case is designed as a moving magnet actuator. Power is supplied to the drive 24 via a control unit 26 of the circuit breaker 10. Consequently, the mechanical switch 20 is actuated through the associated drive 24 via the control unit 26 of the switching device of the circuit breaker 10. The actuation takes place in this case when a fault condition has been detected via a sensor 28 that is incorporated in the additional current path 16. For this purpose, the sensor 28 is designed to sense the electric current flowing through the additional current path 16, and is connected by a signal to the control unit 26. The sensor 28 is designed in the manner of a shunt, and has a measurement resistor that is bridged via an operational amplifier or the like so that the voltage arising across the measurement resistor can be detected via the control unit 26. In this case, an opening of the mechanical switch 20 takes place when a short-circuit current or an overcurrent is present, which is to say, for example, ten times or three times the rated current of the circuit breaker 10 for an associated time period in each case.

Upon opening of the mechanical switch 20, it is possible that an arc forms between the moving contacts and the fixed contacts so that the flow of electric current between the two terminals 14 continues despite the opened mechanical switch 20. On the one hand, extinguishing chambers (not shown in detail) are present for extinguishing the arcs. On the other hand, the switching device 12 includes a second current path 28, which is wired in parallel with the first current path 16. Consequently, the two terminals 14 are also electrically connected to one another via second current path 28 electrically wired in series with the additional current path 16. When corresponding arcs are present across the mechanical switch 20, the second current path 28 is placed in the electrically conductive state via the control unit 26. Consequently, the electric current commutates from the first current path 18 to the second current path 28, as a result of which the arcs across the mechanical switch 20 are extinguished. Then the second current path 28 is placed in the electrically nonconductive state via the control unit 26 yet again, so that no flow of electric current between the terminals 14 is possible anymore.

The second current path 28 has a passive bridge rectifier 30, which thus is formed by four diodes 32. The bridge rectifier 30 has AC voltage side 34, which is formed by two AC voltage side terminals 36. Each of these is routed to one of the terminals 14. Consequently, the AC voltage side 34 is connected to the terminals 14. The bridge rectifier 30 also includes a DC voltage side 38, which is formed by two DC voltage side terminals 40. Each AC voltage side terminal 36 makes electrical contact with both DC voltage side terminals 40 through one of the diodes 32 in each case, wherein the reverse directions of the respective two diodes 32 are different.

The two DC voltage converters 40 are electrically connected to a switch unit 42, so that the DC voltage side 38 is electrically connected via the switch unit 42. The switch unit 42 is actuated via the control unit 26, namely to extinguish the arcs. On account of the bridge rectifier 30, the electric current always flows in the same direction in this case, regardless of the direction in which it flows between the two terminals 14.

The switch unit 42 has two semiconductor switches 44, which are electrically wired in series, wherein the series connection is routed to the DC voltage side terminals 40. The two semiconductor switches 44 are actuated via the control unit 26, by which means a suitable control voltage is applied so that the semiconductor switches 44 are either electrically conductive or electrically nonconductive. In this case, the two semiconductor switches 44 are arranged such that the electric current can only be switched in a single direction, namely the direction specified via the bridge rectifier 30. Consequently, a cascode is formed. One of the semiconductor switches 44 is designed as a MOSFET, and the other as an IGBT.

The two semiconductor switches 44 are electrically bridged via one resistive element 46 each, and therefore the resistive elements 46 are electrically wired in series between the two DC voltage side terminals 40. The resistive elements 46 are identical in design to one another, and a voltage divider is provided by this means. Consequently, the voltage present across each of the semiconductor switches 44 is one half of the voltage present at the terminals 14 when the circuit breaker 10 is in the electrically nonconductive state, which reduces the demands on the semiconductor switches 44. To change the switching state of the switch unit 42, the semiconductor switches 44 are actuated essentially simultaneously, namely each placed in the electrically conductive state or in the electrically nonconductive state.

The resistive elements 46 are designed as varistors. If synchronous control of the semiconductor switches 44 is not accomplished via the switch unit 26, for example when the switches are to be placed in the electrically conductive state, with this occurring prematurely in the case of one of the semiconductor switches 44, then the electric current is carried via the associated varistor on account of the increased voltage arising across the electrically nonconductive semiconductor switch 44. As a result, damage to this semiconductor switch 44 is prevented, on the one hand. On the other hand, the switch unit 42 therefore is placed in the fully electrically conductive state fairly abruptly. Consequently, the demands on the control unit 26 are reduced.

In addition, a temperature-dependent resistor 48, as well as a first ohmic resistor 50 and a series connection composed of a second ohmic resistor 52 and an inductor 54, are wired to one of the semiconductor switches 44, namely to the MOSFET. In a variant that is not shown in detail, at least one or two of these is omitted, for example the first ohmic resistor 50, the series connection composed of the second ohmic resistor 52 and the inductor, and/or the temperature-dependent resistor 48.

The respective other semiconductor switch 44, in this case the IGBT, is bridged via a capacitor 56, which is therefore wired electrically in parallel therewith. Furthermore, an additional sensor 58 is present that is read via the control unit 26, and by which means the voltage arising across the switch unit 42 can be measured.

Consequently, it is also possible to use the circuit breaker 12 for precharging the load 8, which is to say when the load is connected to the DC voltage source 4 for the first time or when any capacitors are discharged. For the duration of the precharging, the mechanical switch 20 and one of the semiconductor switches 44, namely the MOSFET, remain in the electrically nonconductive state. The other semiconductor switch 44, namely the IGBT, is temporarily placed in the electrically conductive state, at least as long as the additional sensor 58 detects that the applied voltage is above a threshold. When the IGBT is electrically conductive, the electric current flows through it as well as through the temperature-dependent resistor 48, the first ohmic resistor 50 or the second ohmic resistor 52/the inductor 56, and is therefore limited. The resistors 48, 50, 52, and the inductor 56 are matched in this case to the load 8 that is used. A current rise is reduced via the inductor 56 in this case.

In order to avoid an overload, the IGBT is placed in the electrically nonconductive state after a certain period of time so that the flow of electric current collapses. Voltage spikes that arise in this process are filtered by the capacitor 56, which avoids stress. After this, the IGBT is again placed in the electrically conductive state so that the electric current again flows across the circuit breaker 10 and can be used for precharging. This is repeated until the load 8 is sufficiently charged. Then the mechanical switch 20 is placed in the electrically conductive state so that a final charging of the load 8 can take place. After that, a check for the presence of the fault condition is again made by the circuit breaker 10, and the switching device 12 is placed in the electrically nonconductive state if necessary.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A switching device comprising:
two terminals that are electrically connected via a first current path that has a mechanical switch; and
a second current path that is electrically wired in parallel with the first current path and that has a bridge rectifier with an AC voltage side and a DC voltage side, the AC voltage side being connected to the two terminals, and the DC voltage side being electrically connected via a switch unit.

2. The switching device according to claim 1, wherein the switch unit has at least two semiconductor switches electrically wired in series that are each electrically bridged via resistive elements.

3. The switching device according to claim 2, wherein the resistive elements are identical in design to one another.

4. The switching device according to claim 2, wherein the resistive elements are varistors.

5. The switching device according to claim 2, wherein an ohmic resistor is electrically wired in parallel with one of the semiconductor switches.

6. The switching device according to claim 5, wherein a capacitor is electrically wired in parallel with another of the semiconductor switches.

7. A circuit breaker comprising:
the switching device according to claim 1; and
a sensor that is connected via a signal to a control unit, via which the switching device is actuated.
